(19) United States
(12) Patent Application Publication
(10) Pub. No.: US 2002/0006739 A1
(43) Pub. Date: Jan. 17, 2002

(54) METHOD FOR MANUFACTURING A SEMICONDUCTOR DEVICE

(76) Inventor: TOMOE YAMAMOTO, TOKYO (JP)

Correspondence Address: HUTCHINS, WHEELER & DITTMAR, 101 FEDERAL STREET, BOSTON, MA, 02110, US

(21) Appl. No.: 09/450,351

(22) Filed: Nov. 29, 1999

(30) Foreign Application Priority Data
Nov. 27, 1998 (JP) 337542/1998
Mar. 3, 1999 (JP) 55185/1999

(51) Int. Cl. H01L 21/8234; H01L 21/8244; H01L 21/31; H01L 21/469

(52) U.S. Cl. 438/785

(57) ABSTRACT

In a method for forming a CVD-TiN film onto a tantalum oxide (Ta₂O₅) film, a substrate onto which a tantalum oxide film is formed is heated in the range from 500° C. to 700° C. in an atmosphere that does not react with the tantalum oxide film before the step of forming the CVD-TiN film onto the tantalum oxide film.

### BACKGROUND OF THE INVENTION

1. Field of the Invention

The present invention relates to a method for forming a semiconductor device, particularly to a method for manufacturing a semiconductor device wherein when forming a laminate of a dielectric film made from a metal oxide and a CVD high melting point metal nitride film, a laminate structure is formed so that the leakage current is small.

2. Background of the Invention

In recent large-capacity DRAM devices, with an increase in the level of integration of memory cells, there has come a need to make capacitive elements with smaller surface areas. This has lead to the use of a stacked capacitor structure, in which a capacitive element is disposed at the top of a MOSFET for memory cell selection, and in order to increase the amount of charge stored in these small capacitive elements, tantalum oxide (Ta₂O₅), which has a high dielectric constant, has come to be used as a capacitive insulation film of the capacitive elements.

When using Ta₂O₅ as a capacitive insulation film of a capacitive element, either a high melting point metal such as tungsten, or a substance such as polysilicon or phosphor-doped polysilicon is generally used as the upper electrode, this being formed by using a CVD process. When the upper electrode layer is formed, to prevent a reactive gas such as SiH4 or the like from encroaching into the Ta₂O₅ film and causing deterioration of the film quality thereof, the upper electrode is formed after forming a protective film of TiN on the Ta₂O₅ film.

Referring to the Japanese Unexamined Patent Publication (KOKAI) No. 9-219501, the method used in the past to manufacture a capacitive element having a Ta₂O₅ as a capacitive insulation film is described below.

FIG. 8 (a) to FIG. 8 (c) show cross-section views of the substrate for each of the basic process steps in manufacturing a capacitive element according to this method of the past.

First, as shown in FIG. 8 (a), an insulation film 2 is grown on a silicon substrate onto which is formed a MOSFET, after which a contact hole is formed in the insulation film 2 so as to expose the diffusion region of the MOSFET. Then, the contact hole is filled as a lower electrode 3 made of a polysilicon film is formed to a thickness of approximately 3000 nm on the insulation film 2. This lower electrode 3 can also have grown hemispherical grains.

Next, a capacitive film 4 made of a dielectric such as Ta₂O₅ is formed to a thickness of approximately 10 nm on the stack electrode 3, using the CVD process.

Next, as shown in FIG. 8 (b), a CVD film forming system is used to form a CVD-TiN film on the Ta₂O₅ film 4 to serve as a protective film.

After growing the CVD-TiN film 5, as shown in FIG. 8 (c), a polysilicon film 6 is grown, after which the CVD-TiN film 5 and the polysilicon film 6 are patterned to form a plate electrode 7.

Referring to FIG. 9 to FIG. 11, the process steps of growing the CVD-TiN film will be described in further detail. FIG. 9 to FIG. 11 show the schedule of introducing gases in the process of forming a CVD-TiN film.

The process of growing the CVD-TiN film 5 has steps of heating the substrate, growing a film, and performing reduction and more detail as shown in FIG. 9 to FIG. 11, these are a step of raising the temperature, a step of forming a protective film, a step of growing a film, and a step of lowering the temperature.

In the gas introduction schedule shown in FIG. 9, after establishing a prescribed vacuum within the chamber, an inert gas is introduced thereinto as the temperature of the substrate is raised. At the point at which the substrate temperature is substantially constant, a source gas including titanium is introduced and thermally broken down, so as to form a film having titanium as it major component on the Ta₂O₅ film 5.

Next, a reducing gas including nitrogen is introduced into the chamber and caused to react with the source gas containing titanium, so that a TiN film having titanium as its major component is grown on the film. The CVD-TiN film 5 is a laminate of a film having titanium as a major component a TiN film.

The source gas containing titanium is either introduced substantially simultaneously with the rise in temperature of the substrate, as shown in FIG. 10, or is introduced after the introduction of the inert gas and immediately before introducing the reducing gas containing nitrogen, as shown in FIG. 11. In either case, the source gas containing titanium is introduced before the reducing gas containing nitrogen.

In the prior art, the above-noted gas introduction schedule was followed, with thermal breakdown of the source gas containing titanium forming a film having titanium as it major component on the Ta₂O₅ film 4, this film preventing contact between the reducing gas containing nitrogen, to be introduced afterward, and the Ta₂O₅ film 4, thereby offering protection from deterioration of the Ta₂O₅ film.

When growing a TiN film, a gas such as titanium tetrachloride (TiCl₄), tetrakis dimethyl amino titanium (TDMAT), tetrakis diethyl amino titanium (TDEAT) or the like is generally used, with ammonia (NH₃), MMH, or the like used as the reducing gas containing nitrogen, and helium, argon, or nitrogen used as the inert gas.

The substrate temperature is 400° C. to 700° C., and in the case of using NH₃ as the reducing gas containing nitrogen, the temperate of the substrate is in range from 400° C. to 550° C. The vacuum pressure within the film-growing chamber of the CVD film-growing apparatus is in the range of several Torr to 20 Torr.

After the film-growing step, at the step of purging gas from the film-growing chamber, an inert gas different from the TiCl₄ gas or NH₃ gas is used, so as to purge the film forming chamber of the gas mixture or unreacted gas.

In the above-described method of the past, however, with a capacitive element using a CVD-TiN film as a protective film, there is the problem of a greater than expected leakage current flowing in the Ta₂O₅ film, thereby making it difficult to increase the capacitance, and by extension making it difficult to manufacture a semiconductor device with a capacitive element having a high level of integration.

While in the above description, the example of growing a CVD-TiN film on the capacitive film of Ta₂O₅ was used, the problem arising being that of excessive leakage current flowing in the CVD-TiN film, this is not the only problem. For example, in the case in which a Ta₂O₅ film is used as a gate oxide film, over which there is sequential lamination of a TiN film as a gate electrode layer, and a polysilicon layer or tungsten layer, there was the problem of difficulty in reducing the leakage current, and this problem prevents the manufacture of a semiconductor device with good transistor characteristics.

Further, while the foregoing description was for the example in which a Ta₂O₅ film is used as a dielectric film, with a CVD high melting point metal nitride film as the CVD-TiN film, the same problem occurs when using a dielectric film made from a different metal oxide, or when using a different CVD high melting point metal nitride film.

In the process of attempting to ascertain the cause of a large leakage current in a capacitive insulation film when forming a capacitive element by the method according to the prior art, believing that using the prior art method of growing a CVD-TiN film, when a CVD-TiN film is grown on a Ta₂O₅ film, because NH₃ gas is introduced after introducing the source gas containing titanium, there is a deterioration of the Ta₂O₅ film, thereby causing a large leakage current, the inventor of the present invention conducted the following experiments.

### EXPERIMENTAL EXAMPLE 1

A film growing experiment was conducted by growing a CVD-TiN film, using the processing steps, chamber pressures, gas types, and gas flows shown in FIG. 3.

(1) First, as shown in FIG. 12, the sample wafer was a wafer produced by forming a DOPOS film having a film thickness of 5000 Angstroms as a lower electrode on a 6-inch silicon wafer, after which a Ta₂O₅ film was formed to a thickness of 100 Angstroms as a capacitive insulation film. After growing the Ta₂O₅ film, the sample wafer was stored for one month before growing the TiN film.

The sample wafer was inserted into a CVD film growing apparatus, the chamber of which was exhausted to a vacuum of 0.1 m Torr. The time required for this exhausting step was 10 to 60 seconds.

(2) Next, moving to the substrate heating step, the NH₃ gas at 400 sccm was introduced into the film growing chamber, the partial pressure of the NH₃ gas (the same as the pressure in the chamber at this point) being held at 0.3 Torr, and the wafer heated to a temperature of 600° C., this temperature being then held. The time required for this substrate heating step was 50 to 70 seconds.

(3) Then, moving to the gas flow stabilization step, the change in the flow of gas into the chamber was steadied so as to stabilize the gas flow, this being a preparatory period before moving to the step of growing a CVD-TiN film.

N₂ gas at 3000 sccm flow is then introduced into the film growing chamber, and the flow of the NH₃ gas is reduced to 120 sccm, so as to raise the pressure in the chamber to 20 Torr. At this point, the NH₃ gas partial pressure was 0.8 Torr. The amount of time required for the gas flow stabilization step was 10 seconds.

(4) Moving to the film growing step, the chamber pressure was maintained as TiCl₄ gas at a flow of 40 sccm was introduced into the chamber, and a CVD-Ti/TiN film was grown.

(5) The chamber pressure, and the N₂ gas flow were then held at the same values as in the film growing step as the flow of the TiCl₄ was brought to zero and the flow of the NH₃ gas was increased to 1000 sccm, thereby bringing the partial pressure of the NH₃ gas to 5 Torr, so as to subject the CVD-TiN film to NH₃ annealing, and growing a TiN film having a thickness of 100 Angstroms. The time required for the NH₃ annealing step was 30 seconds.

(6) Next, moving to the purging step, a gas other than N₂ was introduced, and a vacuum pulled so as to bring the chamber pressure down to 0.1 m Torr. The time required for the purging step was 10 to 30 seconds.

(7) Next, the introduction of N₂ gas was stopped, and exhausting was done.

(8) Next, moving to the step of forming a WSi film, a Wsi film having a thickness of 1100 Angstroms was formed on the TiN film as an upper electrode, resulting in a sample wafer which has a capacitive element as shown in FIG. 12.

(9) Next, as shown in FIG. 12, a voltage of 1.2 V is applied between the WSi and DOPOS films of the sample wafer, and current within the surface of the wafer is measured at 69 points to measure the leakage current, in addition to measuring the capacitance.

The results of measuring the leakage current are indicated in Table 1, which shows the minimum value within the surface, the value over 50% of the surface distribution, and the maximum value within the surface. The capacitance value over 50% of the surface is indicated as Tox in Table 1, this value being smaller, the larger is the capacitance value.

Tox is given by the following expression:

$$\begin{matrix}Tox = ϵ0 \cdot ϵ r \cdot S / Q \\ = 8.854 \times {10}^{- 10} \times 3.82 \times electrode surface \times capacitance value\end{matrix}$$

In the above, ε 0 is the dielectric constant of a vacuum, corresponding to 8.854×10⁻¹⁴,

ε r is the relative dielectric constant of SiO2, corresponding to 3.82,

S is the electrode surface area, and Q is capacitance value.

### EXPERIMENTAL EXAMPLES 2 TO 4

With the exception of making the NH₃ gas partial pressures 1, 5 and 10 Torr, in these examples, similar to example 1, a capacitive element was fabricated and the leakage current and capacitive thereof was measured.

The results are as shown in Table 1.

### EXPERIMENTAL EXAMPLE 5 AND PAST EXAMPLE

For example 5, after growing a Ta₂O₅ film, the wafer was kept between 1 and 2 days, after which, similar to example 1, a TiN film was grown and a capacitive element formed thereon.

In the case of experimental example 6, on a wafer produced under the same conditions as experimental example, with the exception of using the same film growing method and growing conditions as disclosed in the Japanese Unexamined Patent Application publication H9-219501, the capacitive element was fabricated in the same manner as in the experimental example 1, this corresponding to the so-called prior art.

For both experimental examples 5 and 6, similar to the case of experimental example 1, the leakage current and capacitance were measured, the results being as shown in Table 2.

By adjusting Table 1 taking the measured values of leakage current of 50% of the surface and the Tox value of Table 1 as 1, we obtain Table 3. Similarly, by adjusting Table 2 taking the measured values of leakage current of 50% of the surface and the Tox value as 1, we obtain Table 4.

As can be seen from Table 3, there is a significant increase in leakage current and a reduction in capacitance value in experimental examples 3 and 4 in comparison with experimental examples 1 and 2. That is, when the partial pressure of the NH₃ gas exceeds 1 Torr, there is a significant increase in leakage current and a reduction in capacitance. Therefore, this can be taken as meaning that if a capacitive element-having a small leakage current is to be fabricated, 1 Torr is a critical value for the partial pressure of the NH₃ gas.

As can be seen from Table 4, in the prior art examples, compared to experimental examples 1 and 2 in which the NH₃ partial pressures for the did not exceed 1 Torr, although the capacitance value was the same, there was a significant increase in the leakage current.

Additionally, it was verified by experiments that, in order to limit the leakage current, the film thickness of the CVD-TiN film should be in the range from 80 to 120 Angstroms, and ideally should be approximately 100 Angstroms.

It was also verified by experiment that, the partial pressure condition for the NH₃ used for the CVD-TiN film is not limited to CVD-TiN films, but can be applied to other high melting point metal nitride CVD films as well.

Further note that the above-mentioned prior art of JPP' 9-219501 discloses a technical conception in that a protective film should be formed between the dielectric film and the high melting point metal nitride film and thus this technology reduces an increment of number of steps so that the production cost would be increased accordingly.

On the other hand, a separate conventional semiconductor device forming method is also available and in that the semiconductor device will be produced as a manner as shown hereunder.

This separate conventional method for producing the semiconductor device will be explained hereunder with reference to FIGS. 8 (a) to 8 (c).

First, as shown in FIG. 8 (a), an insulation film 2 is formed on a silicon substrate 1, after which a contact hole is formed in the insulation film 2. Then, the contact hole is filled as a capacitive electrode 3 of polysilicon having a thickness of approximately 1000 nm is formed on the insulation film 2. An HSG or the like can also be formed on the capacitive electrode.

Next, a capacitive film made of an dielectric such as Ta₂O₅ is formed to a thickness of approximately 10 nm on the stack electrode 3, using the CVD process.

Next, as shown in FIG. 8 (b), a CVD film forming system is used to form a CVD-TiN film on the capacitive film 4, this serving as the plate electrode 5. the CVD-TiN film uses titanium tetrachloride, ammonia, and nitrogen as raw gases, the semiconductor substrate being kept in the CVD film forming chamber (hereinafter referred to simply as the film forming chamber) at a temperature of 400° C. to 700° C. a pressure ranging from several Torr to 20 Torr.

FIG. 13 shows the steps of introducing the gases in the CVD-TiN film forming process. The vertical axis represents the flow of the gas used, while the horizontal axis represents time. The film forming process can be divided into a CVD-TiN film forming step and a step whereby the gas is purged from within the film forming chamber.

In the substrate heating step, ammonia or other gas that reacts with the Ta₂O₅ film is used as the atmosphere in the chamber. At the CVD-TiN film forming step, gas flows of several to 40 sccm of TiCl₄, 100 to 1000 sccm of NH₃, and 100 to 3000 sccm of N2 are introduced.

After the film forming step, there can be a substrate holding step in which the substrate is held in NH₃ gas. At the step of purging gas from the film forming chamber, an inert gas different from the TiCl₄ gas or NH₃ gas is used, so as to purge the film forming chamber of the gas mixture or unreacted gas.

After the film forming step, as shown in FIG. 8(c), after growing a polysilicon film 6, the CVD-TiN film and polysilicon film are patterned, so as to form the plate electrode 5.

In the above-described method of the past, however, with a capacitive element using a CVD-TiN film as a capacitive film, not only does a leakage current occur, but also there is a large reduction in the capacitance achieved.

In the course of investigating the cause of a large leakage current, the inventor discovered the following. Specifically, the inventor discovered using the method of forming a CVD-TiN film in the past, in the substrate heating step that precedes the CVD-TiN film forming step, because NH₃ gas is introduced, the substrate is heated, and then a CVD-TiN film is formed on a Ta₂O₅ film so as to form a plate electrode, reduction of the Ta₂O₅ by the NH₃ occurs, this causing deterioration of the Ta₂O₅ film, which causes an increase in the leakage current.

To prevent deterioration of the Ta₂O₅ film and an increase in the leakage current, when the CVD-TiN film is formed, the substrate is heated in an inert atmosphere of a gas such as nitrogen, argon, or hydrogen, which does not react with Ta₂O₅, after which titanium tetrachloride and ammonia are supplied, and the CVD-TiN film is formed, thereby enabling the maintenance of a high-quality capacitive film, this representing the completion of the present invention.

Accordingly, it is an object of the present invention to provide a method for manufacturing a semiconductor device wherein when forming a laminate of a dielectric film made from a metal oxide and a CVD high melting point metal nitride film, a laminate structure is formed so that the leakage current is small.

Further, it is a separate object of the present invention to provide a method for forming a CVD-TiN that can be used to fabricate semiconductor device such as a capacitive element having a small leakage current.

### SUMMARY OF THE INVENTION

To achieve the above-noted object, and based on the knowledge of the inventors as described above, the present invention has a basic technological conception for manufacturing method for a semiconductor device and a first aspect of the present invention is a method for forming a semiconductor device having a laminated structure of a dielectric film made from a metal oxide which is formed on a surface of a substrate and CVD high melting point metal nitride film directly formed thereover, wherein the dielectric film is directly formed on the dielectric film by introducing a source gas containing the high melting point metal into a chamber in which the substrate is contained, the method comprising a step of treating the substrate in the chamber with at least either one of a gas non-reactive with respect to metal oxide contained in the dielectric film and NH₃ gas with keeping the temperature of the substrate at a prescribed temperature, before the source gas containing the high melting point metal is introduced into the chamber.

And the second aspect of the present invention is a method for forming a semiconductor device having a laminated structure of a dielectric made from a metal oxide and CVD high melting point metal nitride film formed thereover, wherein the dielectric film is directly formed on the dielectric film by introducing a source gas containing the high melting point metal into a chamber in which the substrate is contained, the method comprising, heating of a substrate onto which the dielectric film is formed to a prescribed temperature in an NH₃ atmosphere of no greater than 1.0 Torr and no less than 0.1 Torr before the introduction of the source gas containing the high melting point metal.

Further, the third aspect of the present invention is a method for manufacturing a semiconductor device according to claim 1, wherein the method further comprising, a step, performed before the CVD high melting point metal nitride film forming step, of heating a substrate onto which the dielectric film is formed, in the chamber by introducing therein the non-reactive gas; and a step of forming the high melting point metal nitride film on the dielectric film by introducing a mixtured gas comprising the NH₃ gas, the non-reactive gas the amount of which is identical to or relatively larger than that of the NH₃ gas and the source gas containing the high melting point metal the amount of which being relatively smaller than those of the NH₃ gas and the non-reactive gas.

### BRIEF DESCRIPTION OF THE DRAWINGS

FIG. 1 (a) to FIG. 1 (c) are cross-section views of a substrate for the case in which the first embodiment of the present invention is applied to the manufacturing of a semiconductor device.

FIG. 2 (d) and FIG. 2 (e) are cross-section view of a substrate for the case in which the first embodiment is applied to the manufacturing of a semiconductor device, showing the steps subsequent to the condition shown in FIG. 1 (c).

FIG. 3 is a flowchart showing the schedule of the chamber pressure and introduced gas when growing a CVD-TiN film according to the first embodiment.

FIG. 4 (a) and FIG. 4 (b) are cross-section views of a substrate for the case in which the second embodiment of the present invention is applied to the manufacturing of a semiconductor device.

FIG. 5 (c) and FIG. 5 (d) are cross-section view of a substrate for the case in which the second embodiment is applied to the manufacturing of a semiconductor device, showing the steps subsequent to the condition shown in FIG. 4 (b).

FIG. 6 is a schematic representation showing a cross-section view of a semiconductor device manufactured according to the third embodiment.

FIG. 7 is a flowchart showing the schedule of the chamber pressure and introduced gas when growing a CVD-TiN film according to the third embodiment.

FIG. 8 (a) to FIG. 8 (d) are cross-section views showing the substrate for each of the basic steps in fabricating a capacitive element having a capacitive insulation film made of Ta₂O₅ according to the prior art.

FIG. 9 is a graph showing the gas introduction schedule for growing a CVD-TiN film according to the according to the prior art.

FIG. 10 is a graph showing another gas introduction schedule for growing a CVD-TiN film according to the according to the prior art.

FIG. 11 is a graph showing yet another gas introduction schedule for growing a CVD-TiN film according to the according to the prior art.

FIG. 12 shows a cross-section view of the sample well used in the experiments, and experimental method employed.

FIG. 13 is a graph showing the gas introduction steps when forming a CVD-TiN film by the method of the past.

FIG. 14 is a graph showing the gas introduction steps when forming a CVD-TiN film according to the one embodiment of the present invention.

FIG. 15 is a cross-section view showing the application of the second embodiment of the present invention to a laminate structure made when fabricating a capacitive element.

FIG. 16 is a cross-section view showing the application of the third embodiment of the present invention to a laminate structure made when fabricating a capacitive element.

### DESCRIPTION OF THE PREFERRED EMBODIMENTS

Preferred embodiments of the present invention will be described below, with reference being made to relevant accompanying drawings.

As mentioned above, the basic technological conception of the present invention is a method for forming a semiconductor device having a laminated structure of a dielectric film made from a metal oxide which is formed on a surface of a substrate and CVD high melting point metal nitride film directly formed thereover, wherein the dielectric film is directly formed on the dielectric film by introducing a source gas containing the high melting point metal into a chamber in which the substrate is contained, the method comprising a step of treating the substrate in the chamber with at least either one of a gas non-reactive with respect to metal oxide contained in the dielectric film and NH₃ gas with keeping the temperature of the substrate at a prescribed temperature, before the source gas containing the high melting point metal is introduced into the chamber.

More specifically, in the method for forming a semiconductor device of the present invention, the treating step can be serving as a flow stabilizing step for stabilize a gas flow used in the chamber and further the non-reactive gas can be introduced in the flow stabilizing step.

On the other hand, in the method-for forming a semiconductor device of the present invention, the treating step may comprise a step for heating the substrate and the flow stabilizing step which is performed after the heating step has been completed.

In the method for forming a semiconductor device in the present invention, the NH₃ gas may be introduced into the chamber in the heating step and in that the NH₃ gas may have NH₃ atmosphere of no greater than 1.0 Torr and no less than 0.1 Torr.

Further, in the method for forming a semiconductor device according to claim 5, the non-reactive gas and the NH₃ gas can be introduced into the chamber in the flow stabilizing step.

In another embodiment of the method for forming a semiconductor device having a laminated structure of a dielectric made from a metal oxide and CVD high melting point metal nitride film formed thereover of the present invention, the dielectric film is directly formed on the dielectric film by introducing a source gas containing the high melting point metal into a chamber in which the substrate is contained, the method comprising heating of a substrate onto which the dielectric film is formed to a prescribed temperature in an NH₃ atmosphere of no greater than 1.0 Torr and no less than 0.1 Torr before the introduction of the source gas containing the high melting point metal.

More specifically, in the method for manufacturing a semiconductor device as mentioned above, the method comprising, a step of heating a substrate to a prescribed temperature, and a step of maintaining the substrate temperature as a gas non-reactive with respect to tantalum oxide is introduced and the flow thereof is stabilized, and wherein the steps being performed before the introduction of a source gas containing a high melting point metal, and NH₃ gas being introduced in either the substrate heating step or the flow stabilization step.

In the method for manufacturing a semiconductor device as mentioned above, the method may further comprising, a step of introducing a source gas containing a high melting point metal, and growing a CVD high melting point metal nitride film after performing the flow stabilization step, and a step of raising the partial pressure of the NH₃ gas in the latter half of the CVD film growing step so that annealing is done by the NH₃ gas.

In the separate embodiment of the present invention, it is provided a method for manufacturing a semiconductor device in that the method further comprising, a step, performed before the CVD high melting point metal nitride film forming step, of heating a substrate onto which the dielectric film is formed, in the chamber by introducing therein the non-reactive gas, and a step of forming the high melting point metal nitride film on the dielectric film by introducing a mixtured gas comprising the NH₃ gas, the non-reactive gas the amount of which is identical to or relatively larger than that of the NH₃ gas and the source gas containing the high melting point metal the amount of which being relatively smaller than those of the NH₃ gas and the non-reactive gas.

In the method for forming a semiconductor device as mentioned above, the method further comprising a step of a gas purging operation in an inside of the the chamber by supplying the NH₃ gas and the non-reactive gas into the chamber with stopping a supply of the source gas containing the high melting point metal thereinto.

Specific embodiments of the present invention will be explained hereunder as examples.

In accordance with the present invention, one specific embodiments of the present invention is one for manufacturing a semiconductor device having a dielectric film made of a metal oxide film and a CVD-grown high melting point metal nitride film formed over the dielectric film, whereby a source gas containing a high melting point metal is introduced and the CVD process is used to grow the high melting point metal nitride film on the dielectric film.

Before introducing the source gas containing the high melting point metal, the substrate, onto which is formed the dielectric film in a NH₃ atmosphere having an NH₃ partial pressure no greater than 1.0 Torr and no less than 0.1 Torr, is heated under prescribed heating conditions.

In the this embodiment, when using the CVD process to form a high melting point metal nitride film onto the dielectric film, as long as the metal oxide dielectric film is one that would be damaged by this process, any film such as a tantalum oxide (Ta₂O₅) film can be used.

In the method of this embodiment, the NH₃ gas used to generate the NH₃ gas atmosphere can be introduced simultaneously with the heating of the substrate, as long as it is introduced before the introduction of the source gain containing the high melting point metal, and can also be introduced at the step of stabilizing the flow when introducing the inert gas.

Specifically, before introducing the source gas containing the high melting point metal, a step of heating the substrate under prescribed heating conditions, and a step of introducing a gas that does not react with tantalum oxide while maintaining while maintaining the substrate temperature, so as to stabilize the flow, are provided.

The MH3 gas is introduced at either the substrate heating step or the flow stabilization step.

Preferably, the substrate should be heated to a temperature of at least 400° C. and no greater than 700° C.

In a preferred embodiment of the present invention, after the flow stabilization step, there is a step of introducing a source gas containing a high melting point metal and using the CVD process to form a high melting point metal nitride film, and a step, in the latter half of the CVD high melting point metal nitride film growing step, of raising the partial pressure of the NH₃ gas and performing thermal processing with the NH₃ gas.

An rarified gas such as argon, nitrogen gas, hydrogen gas, or a combination thereof is introduced as the gas that does not react with a tantalum oxide film.

The method according to the present invention can be applied without limitation to the growing of a CVD high melting point metal nitride film, and is suitable, for example, to the growing of a CVD-TiN film as a high melting point metal nitride film. When applying the present invention in this manner, at least one gas of the group consisting of titanium tetrachloride (TiCl₄), tetrakis dimethyl amino titanium (TDMAT), tetrakis diethyl amino titanium (TDEAT) is used as the source gas containing the high melting point metal.

The method of the present invention is also suitable for application to the growth of a CVD-WN film, in which case WF₆ is introduced as the source gas containing tungsten.

While the above-mentioned method of the present invention can be applied without restriction to a semiconductor device of any configuration, as long as the structure is a lamination of a CVD high melting point metal nitride over a dielectric film, it is preferable that the semiconductor device be one having a capacitive element, the capacitive film of which is a dielectric film, and the protective film of the capacitive insulation film disposed between the capacitive insulation film and the capacitive element being a CVD high melting point metal nitride film, or a semiconductor device having a MOSFET, the gate insulation film of which is a dielectric film, the lowermost layer of the laminated gate electrode being a CVD high melting point metal nitride layer.

### FIRST EXAMPLE

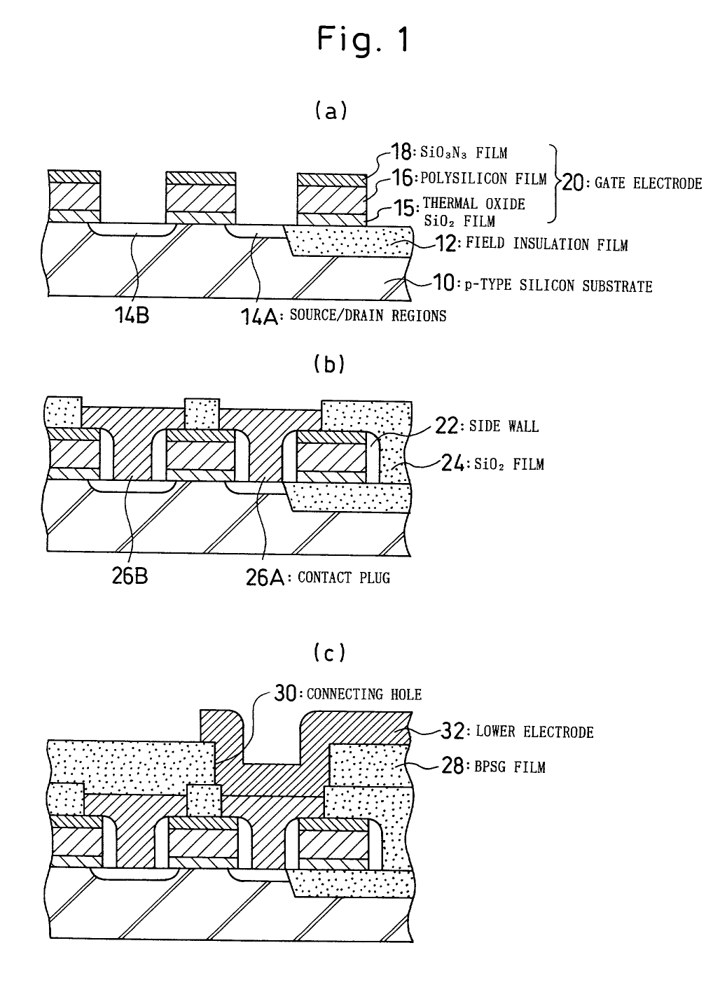

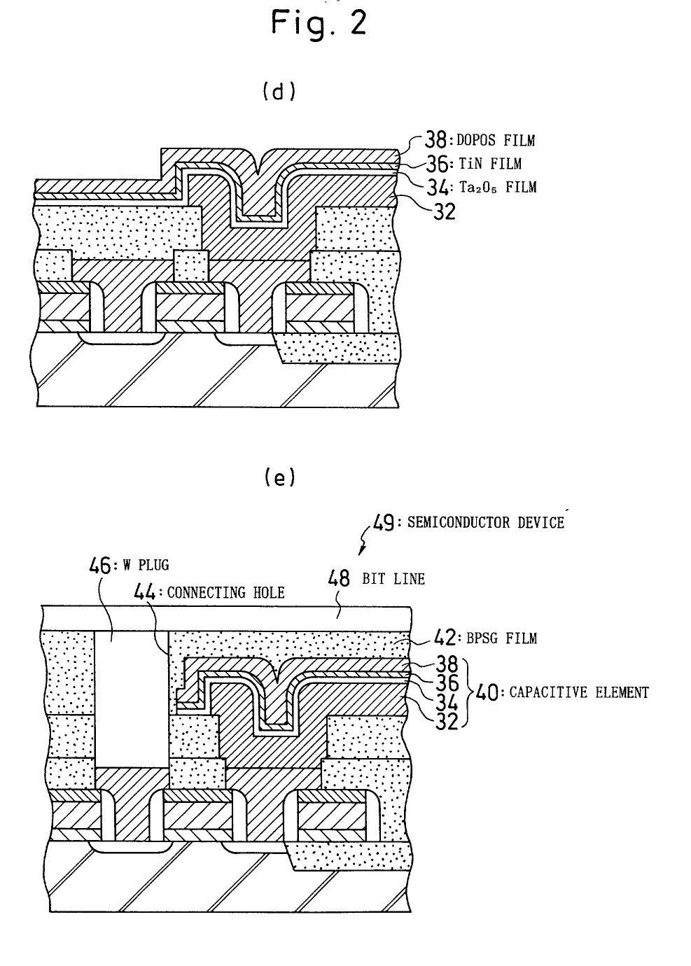

The first embodiment of a method for manufacturing a semiconductor device according to the present invention is applied to the fabrication of a DRAM memory cell having an NMOS device and a capacitive element, FIGS. 1 (a) to (c), and FIGS. 2 (d) and (e) are cross-section views of the substrate when manufacturing a semiconductor device by this method.

In this embodiment, first, as shown in FIG. 1 (a), a field insulation film 12 is formed on a p-type silicon substrate 10, so as to delineate a field region, after which an n-type dopant is ion implanted so as to form the source and drain regions 14A and 14B, respectively, Next, a thermal SiO2 film 15 is grown as a gate oxide film, and the CVD process is sued to grow a polysilicon film 16 and a Si3N4 film 18, these being then patterned and a gate electrode (word line) 20 being formed.

Next, as shown in FIG. (b), a CVD process is used to grow a Si3N4 film on the gate electrode 20, and etching is done to form a side wall 22 made of this Si3N4 film.

Then, the CVD process is used to grow a SiO2 film 24 over the entire surface of the substrate, and a contact hole passing through the SiO2 film 24 is formed so as to expose one side of the source/drain regions A and B. Then a polysilicon film is formed over the entire surface, using a CVD process, and etching is done to form the contact plugs 26A and 26B that fill the contact holes.

Next, a BPSG film 28 is formed over the entire substrate surface, using a CVD process, and a connecting hole 30 is formed so as to pass through the BPSG film 28 and expose the upper surface of the contact plug 26A. Then, using the conditions given below, a polysilicon film 32 having a thickness of 7000 Angstroms is formed over the entire surface of the substrate, using a CVD process, this being patterned so as to form the lower electrode 32 of the capacitive element. The lower electrode 32 can also have grown hemispherical grains.

### Film Growing Conditions

Substrate temperature: 550° C.

Pressure: 2 Torr

SiH4 flow: 1600 sccm

PH3 flow: 60 sccm

Next, as shown in FIG. 2 (d), a Ta₂O₅ film having a film thickness in the range of 20 Angstroms to 200 Angstroms (for example 100 Angstroms) is formed on the lower electrode by a CVD process, using the following conditions.

### Film Growing Conditions

Substrate temperature: 450° C.

Pressure: 0.5 Torr

Gas flow Ta₂O₅: 0.1 ml/minute

O₂: 2 SLM

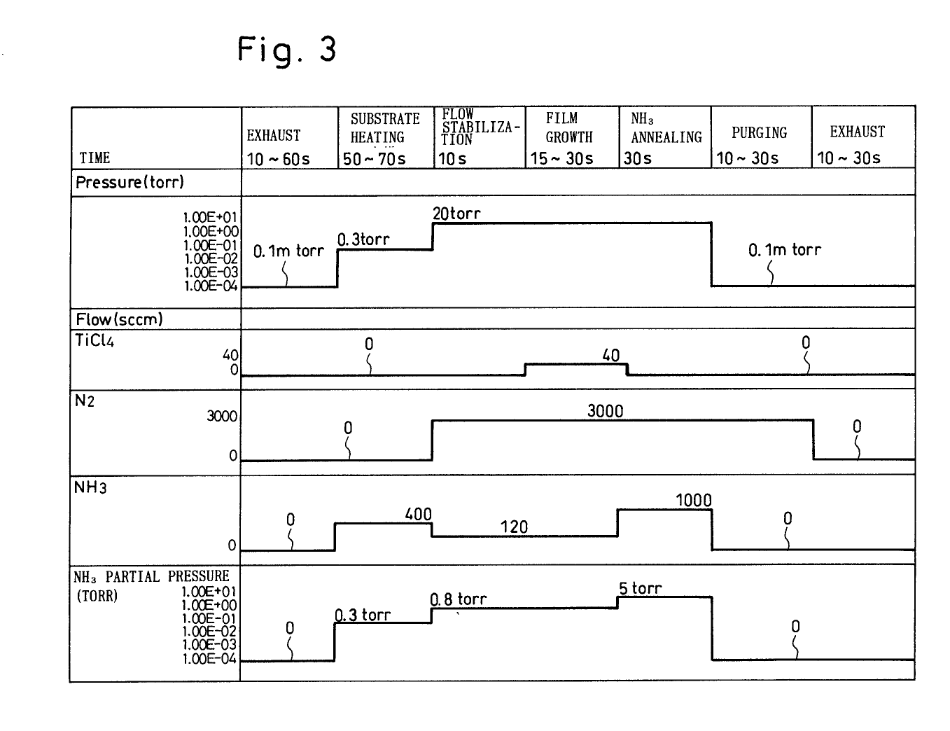

Next, a CVD process is used, with the same conditions and gas introduction schedule as described for the experimental example 1, so as to form a TiN film 36. Following the flowchart of FIG. 3, the following is done.

(1) The substrate is transported into the CVD film growing apparatus and the chamber is exhausted to achieve a pressure therein of 0.1 m Torr. The time required for this exhausting step is 10 to 60 seconds.

(2) Next, moving to the substrate heating step, NH₃ gas is introduced into the chamber with a flow of 400 sccm, and the partial pressure of the NH₃ gas is maintained at 0.3 Torr (which at this point is the same as the chamber pressure), the substrate being heated to 600° C. and held at this temperature. The time required for the substrate heating step is 50 to 70 seconds.

It should be noted that, while this embodiment is described for the case of introducing NH₃ gas in the substrate heating step, this is not an imposed restriction, it being possible to introduce the NH₃ gas at other steps as well, as long as it is introduced before the film growing step.

(3) Next, moving to the gas flow stabilization step, the change in the flow of gas into the chamber is steadied so as to stabilize the gas flow, this being a preparatory period before moving to the step of growing a CVD-TiN film. N2 gas at 3000 sccm flow is then introduced into the film growing chamber, and the flow of the NH₃ gas is reduced to 120 sccm, so as to raise the pressure in the chamber to 20 Torr. At this point, the NH₃ gas partial pressure is 0.8 Torr. The amount of time required for the gas flow stabilization step is 10 seconds.

(4) Moving to the film growing step, the chamber pressure is maintained at 20 Torr as TiCl₄ gas at a flow of 40 sccm is introduced into the chamber, and a CVD-Ti film is grown. The time required for the film growing step is 15 to 30 seconds.

(5) The chamber pressure, and the N2 gas flow is then held at the same values as in the film growing step as the flow of the TiCl₄ is brought to zero and the flow of the NH₃ gas is increased to 1000 sccm, thereby bringing the partial pressure of the NH₃ gas to 5 Torr, so as to subject the CVD-TiN film to NH₃ annealing, and growing a TiN film having a thickness of 100 Angstroms. The time required for the NH₃ annealing step is 30 seconds.

(6) Next, moving to the purging step, a gas other than N₂ is introduced, and a vacuum is pulled so as to bring the chamber pressure down to 0.1 m Torr. The time required for the purging step is 10 to 30 seconds.

(7) Next, the introduction of N2 gas is stopped, and exhausting is done.

Next, a CVD process is used to grow a DOPOS (phosphor-doped polysilicon) film 38 having a thickness of 1800 Angstroms on the TiN film 36, using the following conditions.

Substrate temperature: 550° C.

| | |
|---|---|
| Gas flow | SiH₄: 1600 sccm |
| | PH3: 60 sccm |

Then, as shown in FIG. 2 (e), the Ta₂O₅ film 34, the TiN film 36, and the DOPOS film 38 are patterned to form the capacitive element 40. Next, a CVD process is used to form a BPSG film 42 over the entire surface of the substrate, to achieve flatness. It is alternately possible to use a PSG film, a BSG film, or an SiO2 film in place of the BPSG film 42. Flattening can be achieved by reflow, etchback, or chemical mechanical polishing.

Next, a connecting hole 44 is formed through the BPSG film 42 so as expose the upper surface of the contact plug 26B. A CVD process is used to grow a tungsten film over the entire surface of the substrate, and etching or CMP is done to remove the tungsten film on the BPSG film 42, thereby forming a tungsten plug 46 that fills the connecting hole 44.

Next, a CVD-W film or aluminum-film is deposited over the entire surface of the substrate, bit lines are formed and, if necessary, a passivation film (not shown in the drawing) is formed thereover. By doing this, the condition shown in FIG. 2 (e) is achieved. This enables the manufacture of a semiconductor device having a capacitive element and an NMOS device.

Note that in this embodiment of the method for forming a semiconductor device, the high melting point metal nitride film may be a WN film, and wherein WF₆ gas can be introduced as a source gas containing tungsten.

### SECOND EXAMPLE

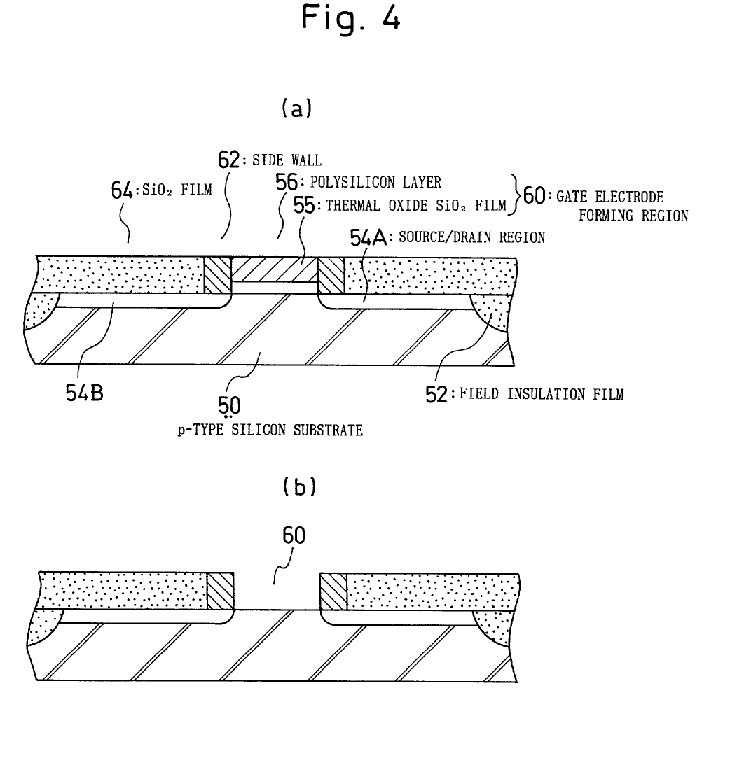

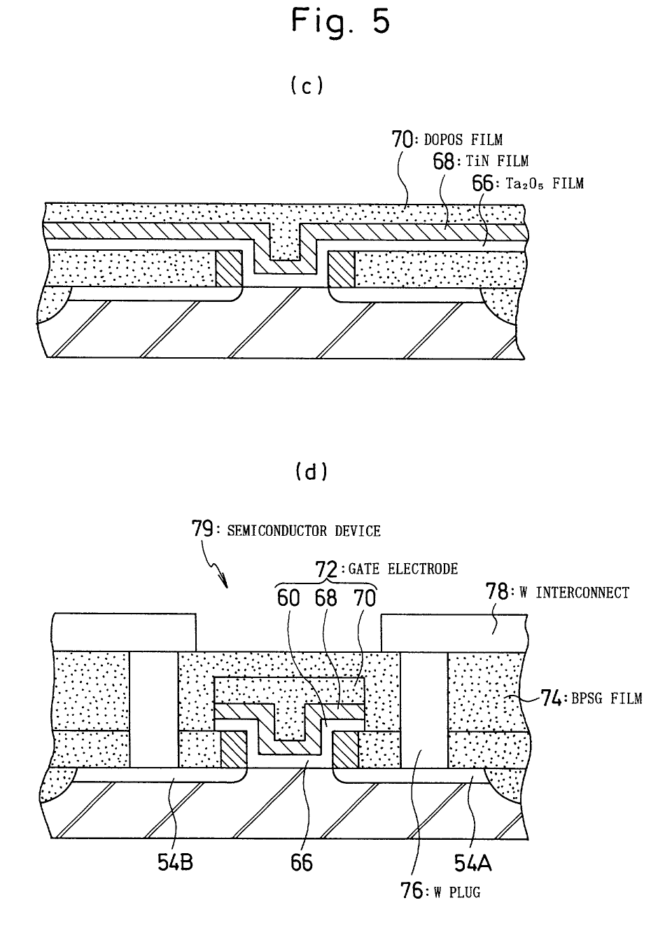

In this embodiment, the method of the present invention is applied to the manufacturing a semiconductor device having an NMOS device with a gate insulation film made of a Ta₂O₅ film and a gate electrode that is a laminate of a TiN film and a DOPOS film. FIGS. 4 (a) and (b) and FIGS. 5 (c) and (d) are cross-section views of the substrate when manufacturing a semiconductor device by this method.

In this embodiment, first, as shown in FIG. 4 (a) and similar to the case of the first embodiment, a field insulation film 52 is formed on a p-type substrate 50 so as to delineate a field region, after which an n-type dopant is ion implanted so as to form the source and drain regions 54A and 54B. The p-type substrate can alternately be a -type well of a silicon substrate.

Next, a thermal oxide SiO₂ film 55 is grown as a gate oxide film, and a CVD process is sued to grow a polysilicon film 56, followed by patterning, so as to form a gate electrode (word line) forming region 60.

The polysilicon film 56 is a dummy for the purpose of defining the gate length and, as is described below, the thermal oxide SiO₂ film 55 and the polysilicon film 56 are removed so as to form a gate electrode that is separate from the word line.

Next, a CVD process is used to form a Si₃N₄ film on the gate forming area 60, and etching is done to form a side wall 62 made of this Si₃N₄ film. Then a CVD process is used to form a SiO₂ film 64 over the entire surface of the substrate.

Then, the SiO₂ film 64 is etched so as to expose the polysilicon film 56, thereby achieving the condition shown in FIG. 4 (a).

Next, as shown in FIG. 4 (b), wet etching is done to remove the thermal oxide SiO₂ film 55 and the polysilicon film 56 so as to open up the gate forming region 60.

Then, as shown in FIG. 5 (c), and similar to the case of the first embodiment, a Ta₂O₅ film 66 and a TiN film 68 are grown, after which a DOPOS film 70 is grown on the TiN film 68. It is alternately possible to use a W-CVD film or a polycide film instead of the DOPOS film 70.

Next, as shown in FIG. 5 (d), the DOPOS film 70, the TiN film 68, and the Ta₂O₅ film 66 are etched so as to form the gate electrode 72. A BPSG film 74 is grown on the DOPOS film 70, and contact holes are formed through the BPSG film 74 so as to expose the source and drain regions, after which tungsten plugs 76 and interconnects 78 are formed, similar to the case of the first embodiment.

By performing the above-described operations, it is possible to achieve a semiconductor device 79 having an NMOS device with the Ta₂O₅ film 66 as a gate insulation film and a gate electrode formed as a laminate of the TiN film 68 and the DOPOS film 70, as shown in FIG. 5 (d).

It is alternately possible to use a PSG film, a BSG film, or an SiO₂ film in place of the BPSG film 74. The interconnect 74 can use aluminum or gold in place of tungsten.

### THIRD EXAMPLE

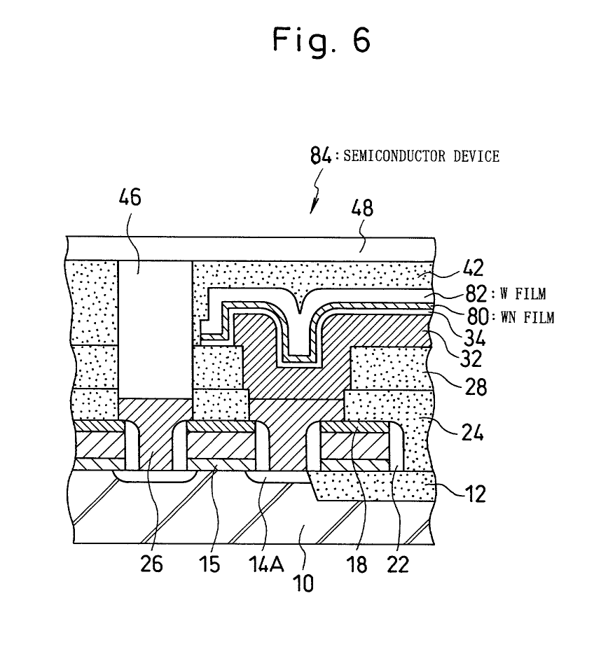

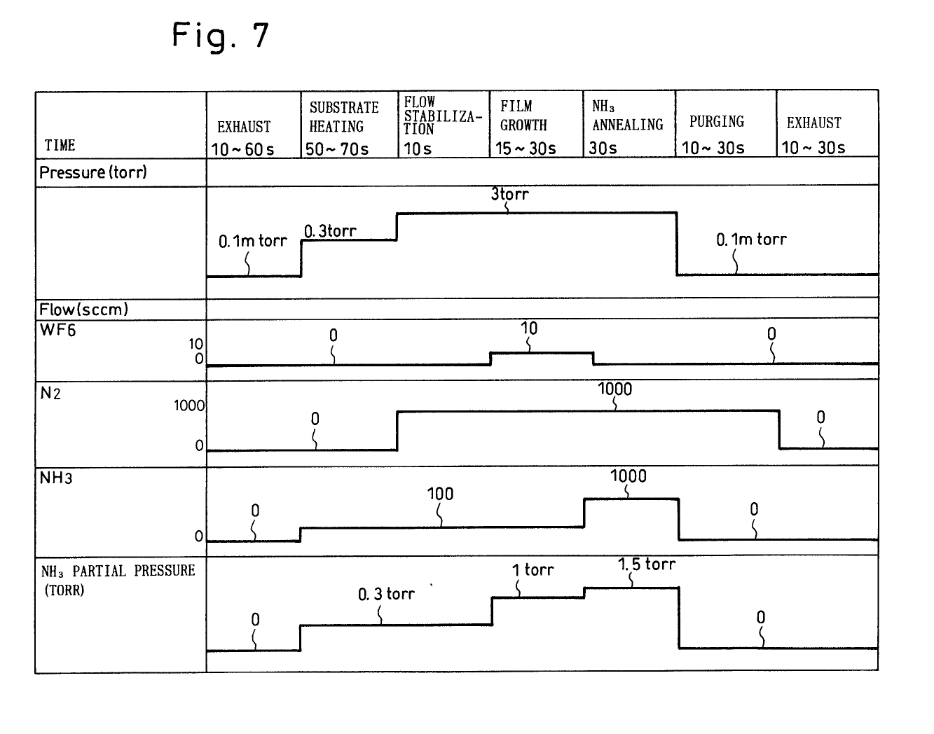

The third embodiment is yet another variation of the method for manufacturing a semiconductor device according to the present invention, FIG. 6 being a cross-section view of a semiconductor device manufactured according to this embodiment, and FIG. 7 being a flowchart showing the schedule of chamber pressure and introduced gas when forming a CVD-WN film according to this embodiment.

With the exception of the fact that a WN film 80 and DOPOS film 38 are formed instead of the TiN film 36 of the first embodiment, this embodiment fabricates a semiconductor device the same as that made by the first embodiment, and enables the manufacture of a semiconductor device 84 having an NMOS device and a capacitive element with a Ta₂O₅ film 34 as a capacitive film.

When growing the WN film 80, a CVD process is used, following the schedule shown in FIG. 7.

(1) The substrate is transported into the CVD film growing apparatus and the chamber is exhausted to achieve a pressure therein of 0.1 m Torr. The time required for this exhausting step is 10 to 60 seconds.

(2) Next, moving to the substrate heating step, NH₃ gas is introduced into the chamber with a flow of 100 sccm, and the partial pressure of the NH₃ gas is maintained at 0.3 Torr (which at this point is the same as the chamber pressure), the substrate being heated to a temperature between 400° C. and 500° C. (for example 450° C.) and held at this temperature. The time required for the substrate heating step is 50 seconds.

It should be noted for this embodiment as well that, while this embodiment is described for the case of introducing NH₃ gas in the substrate heating step, this is not an imposed restriction, it being possible to introduce the NH₃ gas at other steps as well, as long as it is introduced before the film growing step.

(3) Next, moving to the gas flow stabilization step, the change in the flow of gas into the chamber is steadied so as to stabilize the gas flow, this being a preparatory period before moving to the step of growing a CVD-WN film. N2 gas at 1000 sccm flow is then introduced into the film growing chamber, and the flow of the NH₃ gas is reduced to 100 sccm, so as to raise the pressure in the chamber to 3 Torr. At this point, the NH₃ gas partial pressure is 0.8 Torr. The amount of time required for the gas flow stabilization step is 10 seconds.

(4) Moving to the film growing step, the chamber pressure is maintained at 3 Torr as WF6 gas at a flow of 10 sccm is introduced into the chamber, and a CVD-WN film is grown. The time required for the film growing step is 15 to 30 seconds.

(5) The chamber pressure, and the N2 gas flow is then held at the same values as in the film growing step as the flow of the WF6 is brought to zero and the flow of the NH₃ gas is increased to 1000 sccm, thereby bringing the partial pressure of the NH₃ gas to 5 Torr, so as to subject the CVD-WN film to NH₃ annealing, and growing a WN film having a thickness of 100 Angstroms. The time required for the NH₃ annealing step is 30 seconds.

(6) Next, moving to the purging step, a gas other than N2 is introduced, and a vacuum is pulled so as to bring the chamber pressure down to 0.1 m Torr. The time required for the purging step is 10 to 30 seconds.

(7) Next, the introduction of N2 gas is stopped, and exhausting is done.

It has been verified by measurement that sample semiconductor devices manufactured according to the first to third embodiments and having the configurations of the above-noted semiconductor devices 49, 79, and 84, have small leakage currents such as occurred in experimental examples 1 through 5.

In accordance with the present invention, the semiconductor device as produced by the above-mentioned methods has a capacitive element, a dielectric film of which is a capacitive insulation film, a CVD high melting point metal nitride film serving as a protective film disposed between the capacitive insulation film and the capacitive element.

Also in accordance with the present invention, the semiconductor device as produced by the above-mentioned methods has a MOSFET, the gate insulation film of which is a dielectric film, and wherein the CVD high melting point metal nitride layer is the lowermost layer of the laminated gate electrode layer formed on the gate insulation film.

Next specific embodiment will be explained hereunder with reference to the accompanied drawings.

In this embodiment, the method for forming a semiconductor device is one in which a CVD titanium nitride is formed using a CVD process on an dielectric film made of an oxide, whereby before a step in which the CVD-TiN film is formed on the dielectric film, the substrate on which the dielectric film is formed is heated in an atmosphere of a gas that non-reactive with the oxide that forms the dielectric.

The heating before the forming of the CVD-TiN film is done to adjust the substrate temperature to the conditions for formation of the CVD-TiN film, and to eliminated gas that has become adsorbed into the surface of the substrate.

It is preferable that this method for forming a CVD-TinN film be one in which the CVD process is used to form a titanium nitride (TiN) film on a tantalum oxide (Ta₂O₅) film, whereby before the step in which the CVD-TiN film is formed on the tantalum oxide, the substrate onto which the tantalum oxide film is formed is heated in an atmosphere of a gas that does not react with the tantalum oxide.

In the method of forming a CVD-TiN film according to the present invention, by heating the substrate in a gas that does not react with tantalum oxide before forming the CVD-TiN film, there is no deterioration of the capacitive film, thereby enabling the suppression of leakage current.

It is preferable that the heating temperature be at least 400° C. and no greater than 700° C. The inert gas atmosphere that does not react with tantalum oxide does not include NH₃, and this can be, for example, a rarified argon gas, hydrogen gas, or a mixture of any of these gases.

In the step of forming the CVD-TiN film, the film is formed using a gas mixture that includes titanium tetrachloride (TiCl₄) and ammonia (NH₃).

While there is no limitation to the application of the CVD-TiN film formed according to the method of the present invention, if for example a tantalum oxide film is formed as a capacitive film of a capacitive element, and a CVD-TiN film is formed as a plate electrode, it is possible to fabricate a high-quality capacitive element.

### FOURTH EXAMPLE

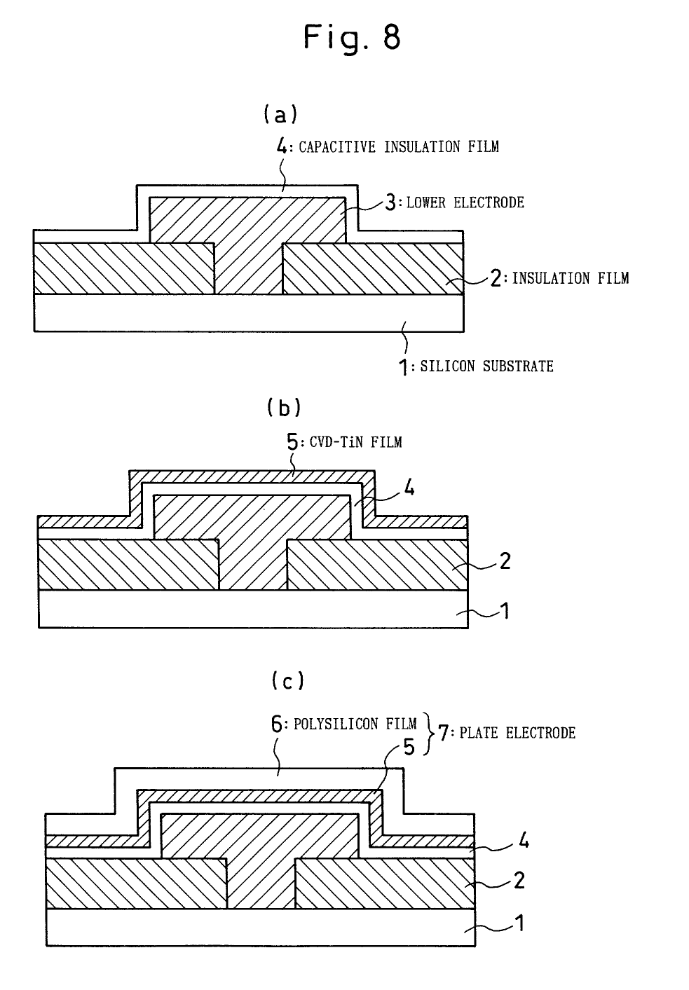

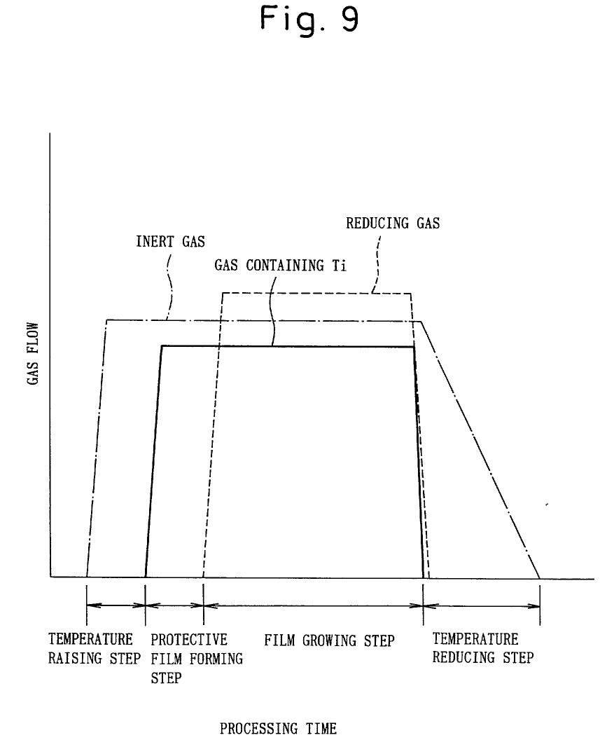

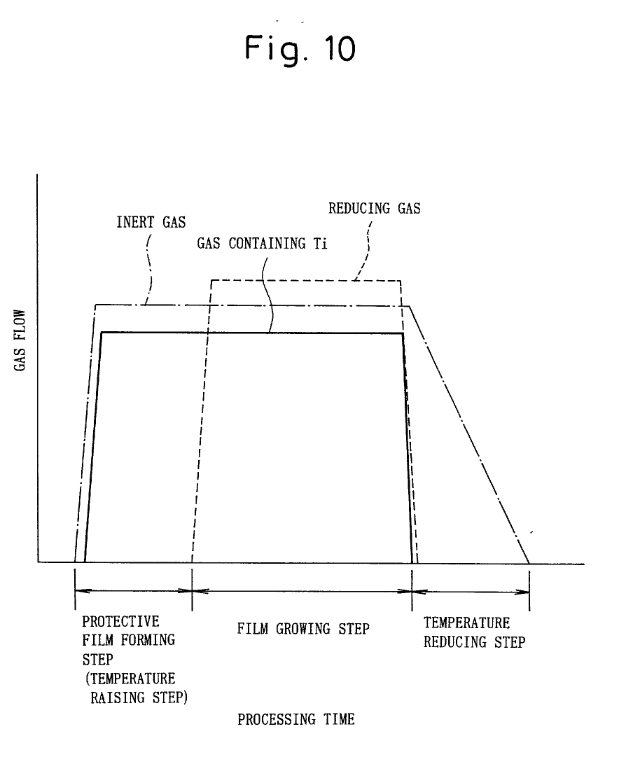

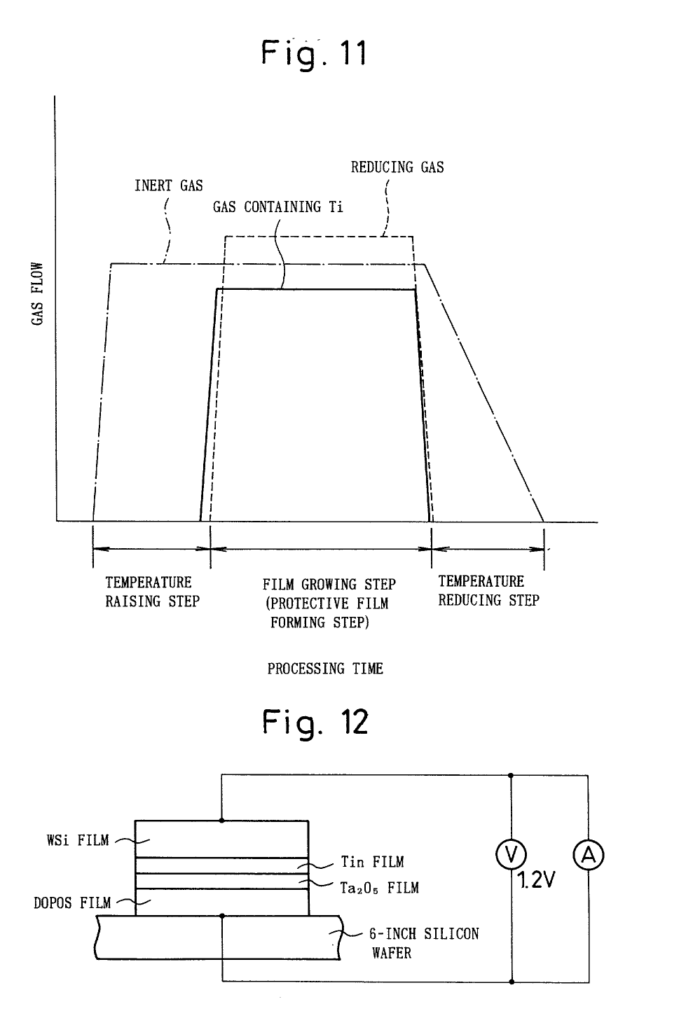

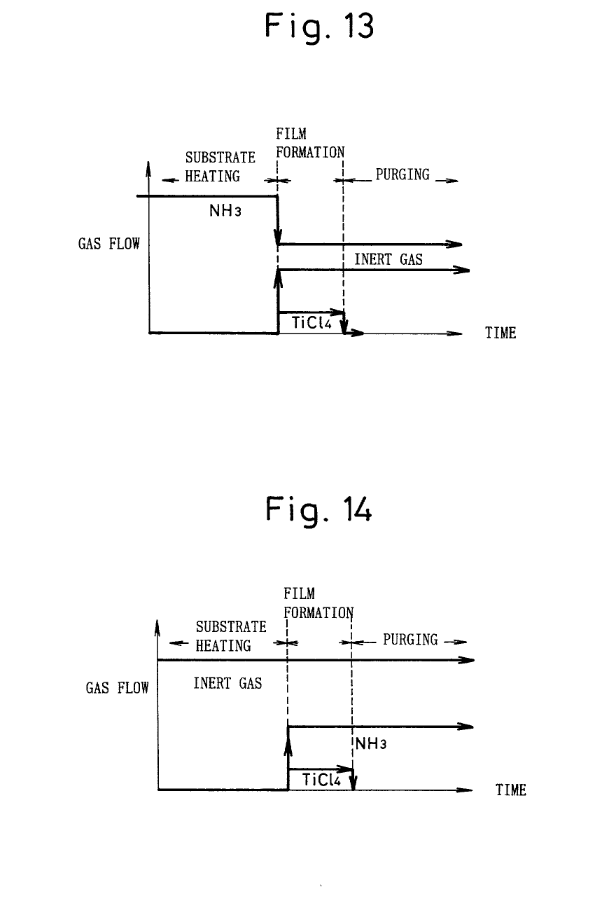

The fourth embodiment of the present invention is one in which a method of forming a CVD-TiN film is applied to the formation of a plate electrode of a capacitive element, FIG. 8 (a) and FIG. 8 (b) showing cross-section views of the laminate structure that occurs when fabricating the capacitive element by applying this embodiment of film forming method.

First, as shown in FIG. 8 (a), an insulation film 2 is formed on a silicon substrate 1, after which a contact hole is formed in the insulation film 2. Then, the contact hole is filled as a capacitive electrode 3 of polysilicon having a thickness of approximately 1000 nm is formed on the insulation film 2. An HSG or the like can also be formed on the capacitive electrode 3.

Next, a capacitive film 4 made of an dielectric such as Ta₂O₅ is formed to a thickness of approximately 10 nm on the stack electrode 3, using the CVD process.

Next, as shown in FIG. 8 (b), a CVD film forming system is used to form a CVD-TiN film on the capacitive film 4, this serving as the plate electrode 5. The CVD-TiN film uses titanium tetrachloride, ammonia, and nitrogen as raw gases, and the substrate is kept at a temperature of 400° C. to 700° C. a pressure ranging from several Torr to 20 Torr.

The conditions for the various steps in forming a CVD-TiN film according to the method of this embodiment are shown in FIG. 14, the horizontal axis of which indicates the times of gas introduction, and the vertical axis of which indicates the gas flow.

In the CVD-TiN film forming process, there is first a step of introducing only a gas that does not react with tantalum oxide or an insert gas, such as N2, and heating the substrate-in this atmosphere, a CVD-TiN film forming step in which TiCl₄ gas and NH₃ gas are added to the N2 gas, and then a purging step of stopping the introduction of the TiCl₄ gas and introducing N2 gas and NH₃ gas to purges the gases in the film forming chamber.

In the step of heating the substrate, in order to remove gas that has become adsorbed into the rear surface of the substrate, the substrate is heated to a temperature in the range 400° C. to 700° C.

The gas atmosphere in the film forming chamber during the substrate heating step is performed using nitrogen, argon, hydrogen or other inert gas, without introducing NH₃ gas or other gas that would react.

In the CVD-TiN film forming step, TiCl₄ gas is introduced at several to 40 sccm, NH₃ gas is introduced at 100 to 1000 sccm, and N2 gas is introduced at 100 to 3000 sccm flow. After this film forming step, there can be a step in which the substrate is held in an NH₃ atmosphere.

The gas purging step, in which gas in the film forming chamber is purged, is performed by using an inert gas other than TiCl₄ or NH₃ to purge gases.

Next, as shown in FIG. 3, a polysilicon film 6 is grown on the plate electrode 5, and this is patterned to obtain the desired capacitive element.

According to the above-noted embodiment of a method for forming a CVD-TiN film, because there is no reduction of the Ta₂O₅ film surface by NH₃ before forming the CVD-TiN film, there is no deterioration of the surface of the surface of the Ta₂O₅ surface, and it is possible to form a titanium nitride film on the surface of the Ta₂O₅ that has small leakage current. It is therefore possible to achieve stable capacitive characteristics with the above-noted embodiment.

### FIFTH EXAMPLE

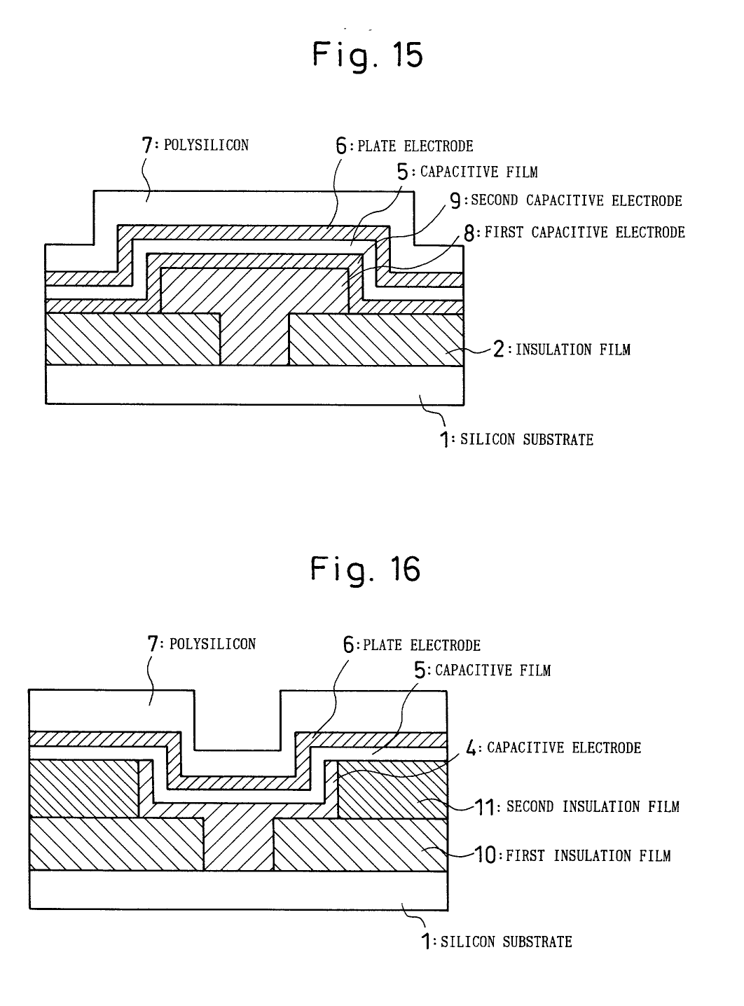

The fifth embodiment of a method for forming a CVD-TiN film according to the present invention as applied to the formation of a capacitive element is shown in cross-section form in FIG. 15.

First, similar to the case of the first embodiment, an insulation film 2 is formed on the silicon substrate 1, after which a contact hole is formed in the insulation film 2. Next, the contact hole is filled as a first capacitive electrode 8 of polysilicon having a thickness of approximately 1000 nm is formed on the insulation film 2. An HSG of the like can also be formed on the capacitive electrode 3.

A second capacitive electrode is then formed over the stack electrode 3, after which a capacitive film 5 of Ta₂O₅ is formed to a thickness of approximately 10 nm, using a CVD process.

A CVD-TiN film if formed on the capacitive electrode 5, this being used as the plate electrode 6. In the substrate heating step when forming the film, an insert gas such as N2 is used. After forming a polysilicon film 7, the polysilicon film 7 and plate electrode 6 are patterned so as to form the capacitive element.

### SIXTH EXAMPLE

The sixth embodiment of a method for forming a CVD-TiN film according to the present invention as applied to the formation of a capacitive element is shown in cross-section form in FIG. 16.

First, as shown in FIG. 16, after forming a first insulation film 10 and then a second insulation film 11 so as to cover the silicon substrate 1, a trench-shaped capacitive electrode 4 is formed. An HSG or the like can also be formed over this capacitive electrode 4.

A capacitive film 5 of Ta₂O₅ is formed over the stack electrode 3 to a thickness of approximately 10 nm, using a CVD process. A CVD-TiN film is formed over the capacitive film 5, this serving as the plate electrode. In the step of heating the substrate when forming the film, an inert gas is used.

Next, after forming a polysilicon film 7, the polysilicon film 7 and plate electrode 6 are patterned to form the capacitive element.

According to the present invention, by heating the substrate in a gas that does not react with the tantalum-oxide before forming a CVD-TiN film on an dielectric film such as a tantalum oxide film, deterioration of the capacitive film does not occur, thereby enabling the suppression of leakage current and the suppression of deterioration of the capacitive characteristics of the capacitive element.

With the method of forming a CVD-TiN film of the past, because the reactive NH₃ gas was used for form the CVD-TiN film, the surface of the Ta₂O₅ film deteriorated because of reduction by the NH₃. With the present invention, however, because an inert gas is used in the substrate heating step, there is no deterioration of the Ta₂O₅ film, thereby enabling the attainment of good capacitive characteristics.

Further in accordance with the present invention, when a high melting point metal nitride film is formed by a CVD process by introducing a source gas containing a high melting point metal, by heating the substrate onto which is formed a dielectric film to a prescribed temperature in an NH₃ atmosphere of no greater than 1.0 Torr and no less than 0.1 Torr before the introduction of the source gas containing the high melting point metal, it is possible to achieve a semiconductor device with good characteristics and a small leakage current.

TABLE 1

| | Leakage current value | | | |
|---|---|---|---|---|
| | 10⁻⁸ [A/cm²] | | Tox [Å] | |
| | Minimm | | Maximm | |
| | value | value | value | value |
| | within | over 50% | within | over 50% |
| | surface | of surface | surface | of surface |
| Experimental example 1 | 2.58 | 3.39 | 17.96 | 32.74 |
| Experimental example 2 | 2.83 | 4.17 | 20.348 | 32.97 |
| Experimental example 3 | 4.606 | 9.98 | 23.8 | 33.25 |
| Experimental example 4 | 5.882 | 11.2 | 25 | 33.87 |

TABLE 2

| | Leakage current Value | | | |
|---|---|---|---|---|
| | 10⁻⁸ A/cm²] | | Tox [Å] | |
| | Minimm | | Maximm | |
| | value | value | value | value |
| | within | over 50% | within | over 50% |
| | surface | of surface | surface | of surface |
| Prior art example | 0.074 | 0.11 | 0.194 | 34.27 |
| Experimental example 5 | 0.032 | 0.074 | 0.128 | 34.35 |

TABLE 3

| | Leakage current value | | Tox | |
|---|---|---|---|---|
| | Minimm | | Maximm | |
| | value | value | value | value |
| | within | over 50% | within | over 50% |
| | surface | of surface | surface | of surface |
| Experimental example 1 | 0.76 | 1 | 5.3 | 1 |
| Experimental example 2 | 0.83 | 1.2 | 6.0 | 1.01 |
| Experimental example 3 | 1.4 | 2.9 | 7.0 | 1.02 |
| Experimental example 4 | 1.7 | 3.3 | 7.4 | 1.03 |

Note: For the leakage current values 3.39 × 10⁻⁸ A/cm² was taken as 1, and for Tox 32, 74 Angstroms was taken as 1.

TABLE 4

| | Leakage current value | | Tox | |
|---|---|---|---|---|
| | Minimm | | Maximm | |
| | value | value | value | value |
| | within | over 50% | within | over 50% |
| | surface | of surface | surface | of surface |
| Prior art example | 1.00 | 1.5 | 2.6 | 1.00 |
| Experimental example 5 | 0.43 | 1 | 1.7 | 1 |

Note: For the leakage current values 0.074 × 10⁻⁸ A/cm² was taken as 1, and for Tox 33, 35 Angstroms was taken as 1.

What is claimed is:

1. A method for forming a semiconductor device having a laminated structure of a dielectric film made from a metal oxide which is formed on a surface of a substrate and CVD high melting point metal nitride film directly formed thereover, wherein said dielectric film is directly formed on said dielectric film by introducing a source gas containing said high melting point metal into a chamber in which said substrate is contained, said method comprising a step of treating said substrate in said chamber with at least either one of a gas non-reactive with respect to metal oxide contained in said dielectric film and NH₃ gas with keeping said temperature of said substrate at a prescribed temperature, before said source gas containing said high melting point metal is introduced into said chamber.

2. A method for forming a semiconductor device according to claim 1, wherein said treating step serving as a flow stabilizing step for stabilize a gas flow used in said chamber.

3. A method for forming a semiconductor device according to claim 2, wherein said non-reactive gas is introduced in said flow stabilizing step.

4. A method for forming a semiconductor device according to claim 1, wherein said treating step comprising a step for heating said substrate and said flow stabilizing step which is performed after said heating step has been completed.

5. A method for forming a semiconductor device according to claim 4, wherein said NH₃ gas is introduced into said chamber in said heating step.

6. A method for forming a semiconductor device according to claim 5, wherein said NH₃ gas has NH₃ atmosphere of no greater than 1.0 Torr and no less than 0.1 Torr.

7. A method for forming a semiconductor device according to claim 5, wherein said non-reactive gas and said NH₃ gas are introduced into said chamber in said flow stabilizing step.

8. A method for forming a semiconductor device having a laminated structure of a dielectric made from a metal oxide and CVD high melting point metal nitride film formed thereover, wherein said dielectric film is directly formed on said dielectric film by introducing a source gas containing said high melting point metal into a chamber in which said substrate is contained, said method comprising:
heating of a substrate onto which said dielectric film is formed to a prescribed temperature in an NH₃ atmosphere of no greater than 1.0 Torr and no less than 0.1 Torr before the introduction of said source gas containing said high melting point metal.

9. A method for manufacturing a semiconductor device according to claim 8, said method comprising:
a step of heating a substrate to a prescribed temperature; and
a step of maintaining said substrate temperature as a gas non-reactive with respect to tantalum oxide is introduced and the flow thereof is stabilized,
said steps being performed before the introduction of a source gas containing a high melting point metal, and NH₃ gas being introduced in either said substrate heating step or said flow stabilization step.

10. A method for manufacturing a semiconductor device according to claim 9, said method further comprising;
a step of introducing a source gas containing a high melting point metal, and growing a CVD high melting point metal nitride film after performing said flow stabilization step: and
a step of raising the partial pressure of the NH₃ gas in the latter half of the CVD film growing step so that annealing is done by the NH₃ gas.

11. A method for manufacturing a semiconductor device according to claim 1, wherein said method further comprising;
a step, performed before said CVD high melting point metal nitride film forming step, of heating a substrate onto which said dielectric film is formed, in said chamber by introducing therein said non-reactive gas; and
a step of forming said high melting point metal nitride film on said dielectric film by introducing a mixtured gas comprising said NH₃ gas, said non-reactive gas the amount of which is identical to or relatively larger than that of said NH₃ gas and said source gas containing said high melting point metal the amount of which being relatively smaller than those of said NH₃ gas and said non-reactive gas.

12. A method for forming a semiconductor device according to claim 11, wherein said method further comprising a step of a gas purging operation in an inside of said said chamber by supplying said NH₃ gas and said non-reactive gas into said chamber with stopping a supply of said source gas containing said high melting point metal thereinto.

13. A method for forming a semiconductor device according to claim 1, wherein said dielectric film is a tantalum oxide (Ta₂O₅) film.

14. A method for forming a semiconductor device according to claim 1, wherein said substrate is heated to a temperature of at least 400° C. and no greater than 700° C.

15. A method for forming a semiconductor device according to claim 1, wherein said non-reactive gas is one gas selected from a rarified gas including nitrogen, argon, hydrogen gas, or a mixture of these gases.

16. A method for forming a semiconductor device according to claim 1, wherein said high melting point metal nitride film is TiN film.

17. A method for forming a semiconductor device according to claim 16, wherein said source gas containing titanium as said high melting point metal, is a gas selected from the group consisting of titanium tetrachloride (TiCl₄), tetrakis dimethyl amino titanium (TDMAT), tetrakis diethyl amino titanium (TDEAT) is used as the source gas containing titanium.

18. A method for forming a semiconductor device according to claim 1, wherein said high melting point metal nitride film is a WN film, and wherein WF₆ gas is introduced as a source gas containing tungsten.

19. A method for manufacturing a semiconductor device according to claim 1, wherein said semiconductor device has a capacitive element, a dielectric film of which is a capacitive insulation film, a CVD high melting point metal nitride film serving as a protective film disposed between said capacitive insulation film and said capacitive element.

20. A method for manufacturing a semiconductor device according to claim 1, wherein said semiconductor device has a MOSFET, the gate insulation film of which is a dielectric film, and wherein said CVD high melting point metal nitride layer is the lowermost layer of the laminated gate electrode layer formed on said gate insulation film.
